(19) United States
(12) Patent Application Publication
(10) Pub. No.: US 2026/0358703 A1
(43) Pub. Date: Nov. 12, 2026

(54) SHADOW MASK AND MANUFACTURING METHOD THEREOF

(71) Applicant: SUNIC SYSTEM LTD., Suwon-si, Gyeonggi-do (KR)

(72) Inventors: In Ho HWANG, Suwon-si, Gyeonggi-do (KR); Jong Jin KIM, Suwon-si, Gyeonggi-do (KR); Yun Kyeong LEE, Suwon-si, Gyeonggi-do (KR)

(21) Appl. No.: 19/485,280

(22) PCT Filed: May 17, 2024
(86) PCT No.: PCT/KR2024/006709

§ 371 Date: Dec. 28, 2025

(30) Foreign Application Priority Data
May 18, 2023 (KR) 10-2023-0064394
Jun. 27, 2023 (KR) 10-2023-0082647

(51) Int. Cl. G03F 7/00; C23C 14/04; H10K 71/16

(52) U.S. Cl. CPC G03F 7/0005; G03F 7/0035; C23C 14/042; H10K 71/166

(57) ABSTRACT

Provided is a manufacturing method of a shadow mask, the manufacturing method including the steps of: forming a conductive layer on a base substrate; laminating a photoresist on the conductive layer and patterning the photoresist in a shape corresponding to a mask pattern; forming a mask sheet by performing electroforming on a region except for the patterned photoresist; forming a mask frame by patterning the base substrate and the conductive layer to expose the mask pattern; and performing light treatment or heat treatment to reinforce bonding force between the mask sheet and the conductive layer before and after forming the mask frame or in a process of forming the mask frame.

### TECHNICAL FIELD

The present invention relates to a shadow mask used for manufacturing an organic light-emitting device, which has micro-scale ultrafine mask patterns, and a method of manufacturing the same.

### BACKGROUND ART

Organic light-emitting diodes (OLEDs) are self-luminous devices that emit light by utilizing an electroluminescence phenomenon that emit light when current flows through fluorescent organic compounds, and since OLEDs do not require a backlight for applying light on non-self-luminous devices, lightweight and thin flat display panels can be manufactured.

In an OLED, except for an anode and a cathode, the remaining layers such as a hole injection layer, a hole transport layer, a light-emitting layer, an electron transport layer, and an electron injection layer are formed as organic thin films, and such organic thin films may be formed on a substrate by a vacuum deposition method or the like.

In the vacuum deposition method, a substrate is placed in a vacuum chamber, a shadow mask having a predetermined pattern formed thereon is aligned with the substrate, and then heat is applied to an evaporation source accommodating a deposition material so that the deposition material evaporated from the evaporation source is deposited on the substrate.

With the recent advancement of displays employing OLEDs toward higher resolution, mask patterns of shadow masks used to implement such displays should also be fabricated in micro-scale dimensions, and various studies have been conducted on techniques for manufacturing shadow masks having fine patterns.

Among such manufacturing techniques, a technique of fabricating a mask sheet by electroforming a metal material such as Invar (an iron-nickel alloy) has been proposed. Invar is an alloy of iron and nickel and has a low coefficient of thermal expansion and thus has an advantage of exhibiting small thermal deformation during deposition.

According to such a technique, after a very thin mask sheet is formed by electroforming, the mask sheet should be separated from a conductive layer that has been used as an electrode, and during this separation process, there is a problem that the mask sheet may be damaged, such as tearing or wrinkling, which makes the fabrication difficult.

### DETAILED DESCRIPTION OF INVENTION

### Technical Problem

The present invention has been devised to solve the above-described problems, and object of the present invention are to provide a shadow mask and a method of manufacturing the same, which allow, by electroforming, a shadow mask having micro-scale ultrafine mask patterns for manufacturing an organic light-emitting device to be manufactured without damage, such as tearing or wrinkling of the mask sheet, and delamination of at least a portion of the mask sheet from a conductive layer to be minimized during a manufacturing process or during use.

The technical problems to be solved by the present invention are not limited to those described above, and other technical problems that are not mentioned herein will be clearly understood by those of ordinary skill in the art to which the present invention pertains from the description below.

### Technical Solution

According to one embodiment of the present invention, there is provided a method of manufacturing a shadow mask, which includes forming a conductive layer on a base substrate, laminating a photoresist on the conductive layer and patterning the photoresist into a shape corresponding to a mask pattern, forming a mask sheet by performing electroforming on regions except for the patterned photoresist, forming a mask frame by patterning the base substrate and the conductive layer to expose the mask pattern, and performing light treatment or heat treatment before, after, or in the forming of the mask frame to enhance bonding strength between the mask sheet and the conductive layer.

In addition, the light treatment may include laser welding using laser light.

In addition, the laser welding may be performed in outer peripheral regions of the mask pattern provided as a plurality of mask patterns on the mask sheet.

In addition, a plurality of welding points of the laser welding may be set to be spaced a regular interval from each other along outer peripheries of the mask patterns.

In addition, the laser welding may be performed so that the mask frame and the mask sheet are welded.

In addition, a plurality of welding points of the laser welding may be set to be spaced a regular interval from each other along outer and inner circumferences of the mask frame.

In addition, when forming the mask frame, a support rib may be formed together between the plurality of mask patterns, and the laser welding may be performed so that the support rib and the mask sheet are welded.

In addition, the heat treatment may include a heating process performed in a furnace or a resistance welding process in which a current and a pressure are applied to a bonding region.

In addition, the heat treatment may be performed after the photoresist is removed from the mask sheet.

In addition, the method may further include, before the forming of the conductive layer forming an adhesive layer for enhancing adhesion between the base substrate and the conductive layer.

In addition, the conductive layer may include copper, and the adhesive layer may include titanium.

In addition, the conductive layer may be formed of a conductive metal doped with an impurity to enhance adhesion between the base substrate and the conductive layer.

In addition, the method may further include, before the forming of the conductive layer forming an insulating film to be used as an etch-stop layer in the patterning of the base substrate.

In addition, the insulating film may be formed of a material including silicon oxide.

Meanwhile, according to another embodiment of the present invention, there is provided a shadow mask including a mask frame, a mask sheet made of Invar and supported by the mask frame, a mask pattern formed on the mask sheet to selectively pass a deposition material therethrough during a deposition process, and an alignment mark formed in an outer peripheral region of the mask sheet for an alignment with a substrate to be deposited, wherein the alignment mark includes a window hole formed to pass through the mask sheet so that light emitted from a light source of an alignment apparatus passes therethrough to obtain an image of an alignment key of the substrate, and a key hole formed to pass through at least one side of the window hole for relative alignment with the alignment key.

In addition, the window hole may have a polygonal shape, and the key hole may be formed at one side of at least one side of the polygonal shape.

In addition, the alignment key may have a form in which a plurality of pattern keys are arranged at regular intervals, and the key hole may include a plurality of pattern holes formed to correspond to shapes and positions of the pattern keys.

In addition, a through hole may be formed in the mask frame at a position corresponding to the alignment mark.

In addition, an auxiliary alignment key may be additionally formed on the substrate, and the alignment mark may further include an auxiliary key hole formed at a position corresponding to the auxiliary alignment key.

Meanwhile, according to still another embodiment of the present invention, there is provided a method of manufacturing the shadow mask, which includes forming a conductive layer on a base substrate, laminating a photoresist on the conductive layer and patterning the photoresist into a shape corresponding to the mask pattern, the window hole, and the key hole, forming the mask sheet by performing electroforming on regions except for the patterned photoresist, and forming the mask frame by patterning the base substrate and the conductive layer to expose the mask pattern, the window hole, and the key hole.

In addition, in the patterning of the base substrate to expose the mask pattern, through holes for exposing the window hole and the key hole may be patterned together.

In addition, before the forming of the conductive layer, forming an adhesive layer for enhancing adhesion may be formed between the base substrate and the conductive layer.

In addition, the conductive layer may include copper, and the adhesive layer may include titanium.

In addition, the conductive layer may be formed of a conductive metal doped with an impurity to enhance adhesion between the base substrate and the conductive layer.

In addition, before the forming of the conductive layer, forming an insulating film to be used as an etch-stop layer may further be performed in the patterning of the base substrate.

In addition, the insulating film may be formed of a material including silicon oxide.

### Advantageous Effects

According to an embodiment of the present invention, in manufacturing a shadow mask having micro-scale ultrafine mask patterns for manufacturing an organic light-emitting device by electroforming, the shadow mask can be manufactured without a process of separating a mask sheet by forming the mask sheet through electroforming and then patterning a base substrate to form a mask frame, thereby preventing damage such as tearing or wrinkling of the mask sheet during the manufacturing process of the shadow mask.

Further, according to an embodiment of the present invention, by enhancing bonding strength between a mask sheet and a conductive layer through light treatment or heat treatment, it is possible to minimize delamination of the mask sheet from the conductive layer during an etching process of a base substrate or during use of a shadow mask (for example, during cleaning of a mask).

Further, according to an embodiment of the present invention, by using an insulating film as an etch-stop layer in the process of forming a mask frame through patterning of a base substrate, damage to the mask sheet caused by an etchant can be prevented.

In addition, according to an embodiment of the present invention, in a shadow mask having micro-scale ultrafine mask patterns for manufacturing an organic light-emitting device, a shadow mask having a novel structure capable of minimizing alignment errors is provided, and specifically, a novel alignment mark structure in which alignment marks of a mask sheet are separately formed as a window hole and a key hole is proposed, and alignment is achieved by aligning an alignment key of a substrate, visible through the window hole, with the key hole of the mask sheet. Accordingly, alignment between the alignment key including a plurality of pattern keys and the key hole including a plurality of corresponding pattern holes can be achieved, thereby providing an Invar shadow mask capable of minimizing alignment errors.

Further, according to an embodiment of the present invention, by forming a mask sheet through electroforming and then patterning a base substrate to form a mask frame, a shadow mask can be manufactured without a process of separating the mask sheet, thereby preventing damage such as tearing or wrinkling of the mask sheet during a manufacturing process of the shadow mask.

### DESCRIPTION OF DRAWINGS

FIG. 1 is a cross-sectional view of a shadow mask for manufacturing an organic light-emitting device related to the present invention.

FIG. 2 is a flowchart illustrating a method of manufacturing a shadow mask according to one embodiment of the present invention.

FIG. 3 is a manufacturing process diagram schematically illustrating processes up to forming a mask sheet of FIG. 2.

FIG. 4 is a plan view of the shadow mask illustrating an example of welding points in a laser welding process.

FIG. 5 is a manufacturing process diagram schematically illustrating forming a mask frame of FIG. 2.

FIG. 6 shows a bottom view and a cross-sectional view of the shadow mask, illustrating another example of welding points in the laser welding process.

FIG. 7 shows a bottom view and a cross-sectional view of the shadow mask, illustrating still another example of welding points in the laser welding process.

FIG. 8 is a manufacturing process diagram illustrating a method of manufacturing a shadow mask according to another embodiment of the present invention.

FIGS. 9 and 10 are manufacturing process diagrams illustrating a method of manufacturing a shadow mask according to still another embodiment of the present invention.

FIG. 11 is a cross-sectional view of a shadow mask for manufacturing an organic light-emitting device according to yet another embodiment of the present invention.

FIG. 12 is a plan view of the shadow mask illustrated in FIG. 11.

FIG. 13 is a plan view of an alignment mark of the shadow mask illustrated in FIGS. 11 and 12.

FIG. 14 is a plan view of an alignment key of the substrate illustrated in FIG. 11.

FIG. 15 is a plan view illustrating a state in which the alignment mark of the shadow mask illustrated in FIG. 13 and the alignment key of the substrate illustrated in FIG. 14 are aligned with each other.

FIG. 16 is a plan view of an alignment mark of a shadow mask according to yet another embodiment of the present invention.

FIG. 17 is a plan view of an alignment key of a substrate according to yet another embodiment of the present invention.

FIG. 18 is a plan view illustrating a state in which the alignment mark of the shadow mask illustrated in FIG. 16 and the alignment key of the substrate illustrated in FIG. 17 are aligned with each other.

FIG. 19 is a flowchart illustrating a method of manufacturing the shadow mask illustrated in FIG. 11.

FIGS. 20 and 21 are manufacturing process diagrams schematically illustrating the method of manufacturing the shadow mask illustrated in FIG. 19.

### DESCRIPTION OF REFERENCE NUMERALS

1, 100: shadow mask,
2: substrate
3: alignment key,
4: pattern key
5: auxiliary alignment key
10, 210: mask frame,
20, 220: mask sheet
22, 222: mask pattern,
25: etching region
31, 241: base substrate,
33, 243: etch-protection layer
35, 245: adhesive layer,
37, 244: mask-frame forming pattern
39, 242: insulating film,
40, 246: conductive layer
42, 247: photoresist
L: laser light
P: welding point
H: heat
212: through hole
223: fine pattern hole
222: mask pattern,
223: fine pattern hole
224: central hole
230: alignment mark
231: window hole
232: key hole
234: pattern hole
236: auxiliary key hole
249: through-hole forming pattern

### Modes of the Invention

The present invention may be modified in various forms and have various embodiments, and thus particular embodiments thereof will be illustrated in the accompanying drawings and described in detail in the detailed description. It should be understood, however, that there is no intent to limit the present invention to the particular forms disclosed, but on the contrary, the present invention is to cover various modifications, equivalents, and alternatives falling within the spirit and scope of the present invention. In describing the present invention, detailed descriptions of well-known technologies will be omitted when it is deemed that such descriptions may obscure the gist of the present invention.

The terms “first,” “second,” and the like may be used to describe various components, but these terms do not limit the components. These terms are only used to distinguish one element from another.

Terms used herein are for the purpose of describing particular exemplary embodiments only and are not intended to be limiting to the present invention. As used herein, singular forms are intended to include plural forms as well, unless the context clearly indicates otherwise. In the present application, it will be further understood that the terms “comprise,” “comprising,” “include,” and/or “including” used in this specification specify the presence of stated features, integers, steps, operations, elements, components and/or groups thereof but do not preclude the presence or addition of one or more other features, integers, steps, operations, elements, components and/or groups thereof.

Hereinafter, embodiments of a shadow mask and a method of manufacturing the same according to the present invention will be described in detail with reference to the accompanying drawings, and in describing the drawings, the same or corresponding components will be denoted by the same reference numerals, and redundant descriptions thereof will be omitted.

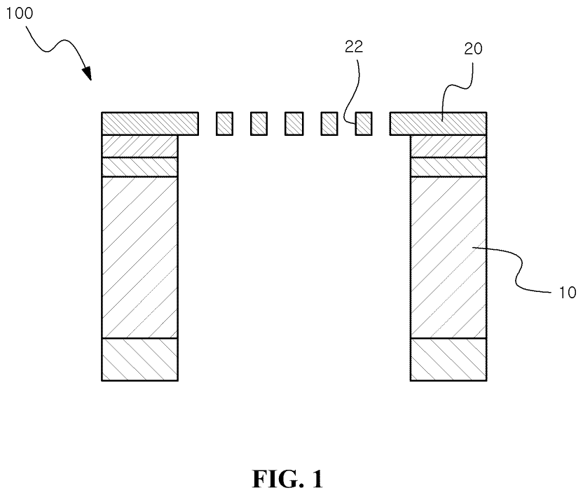

FIG. 1 is a cross-sectional view of a shadow mask for manufacturing an organic light-emitting device related to the present invention.

As illustrated in FIG. 1, a shadow mask 100 for an organic light-emitting device according to the present embodiment includes a mask frame 10 and a mask sheet 20 supported by the mask frame 10.

The mask frame 10 may be supported by a support structure such as a mask holder of vacuum deposition equipment, and may have a shape that supports an edge of the mask sheet 20. The mask frame 10 may have, for example, a ring or donut shape with a through hole formed at the center, a mesh shape in which a plurality of through holes are formed at the center, or the like.

The mask sheet 20 includes mask patterns 22 for selectively allowing a deposition material to pass therethrough during a deposition process. As the deposition material evaporated from an evaporation source of a vacuum deposition apparatus passes through the mask patterns 22 and is deposited onto a substrate, patterns corresponding to the mask patterns 22 may be formed on the substrate.

The mask sheet 20 may be formed of a material including Invar (an iron-nickel alloy). An Invar thin film provided with the mask patterns 22 may be formed on a base substrate 31 by electroforming, and the shadow mask 100 may be manufactured by patterning the base substrate 31.

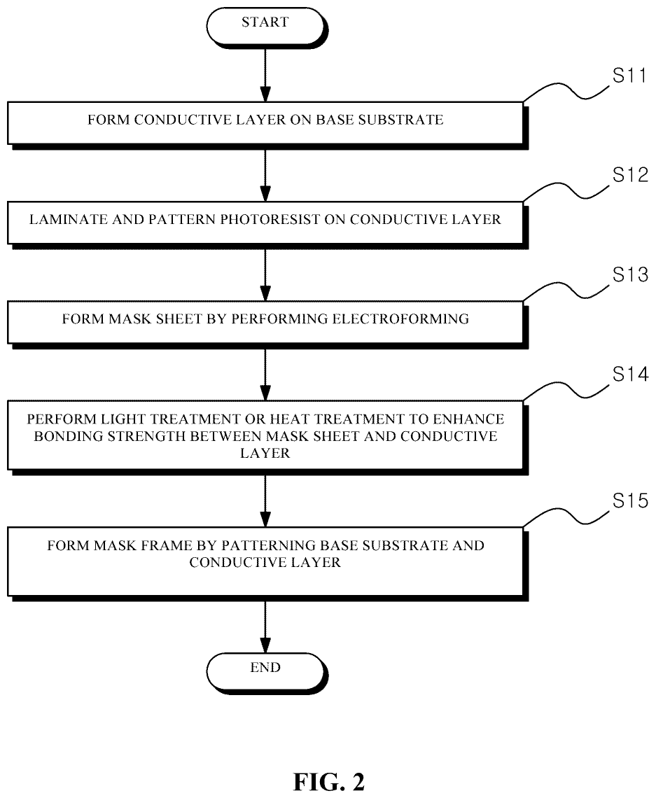

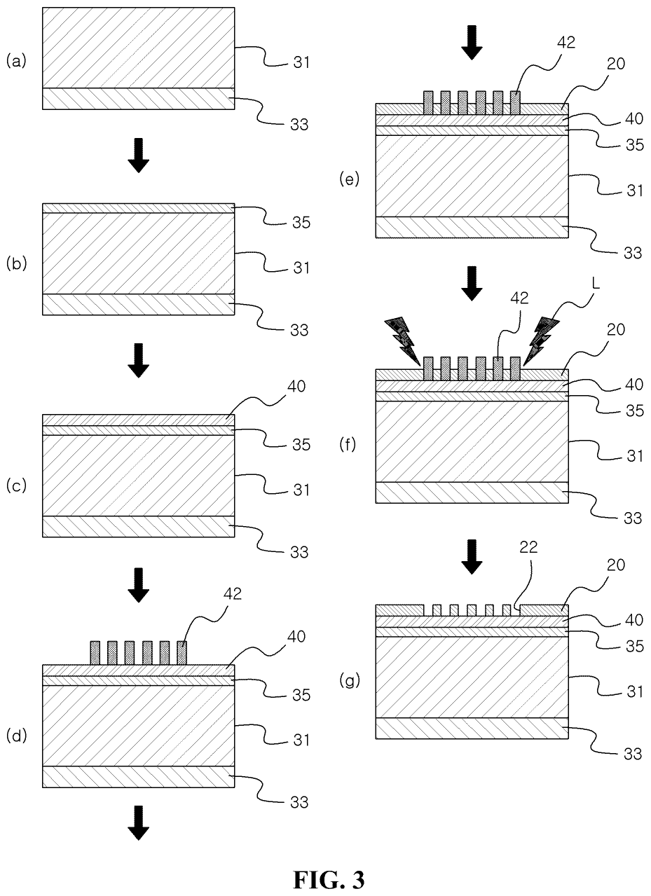

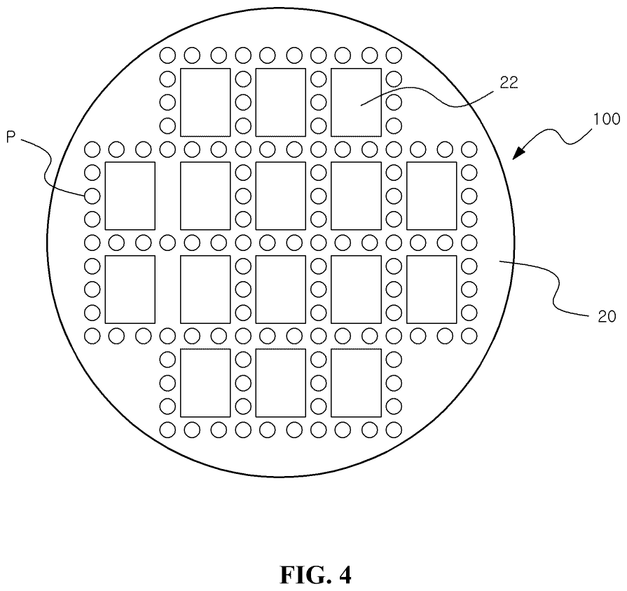

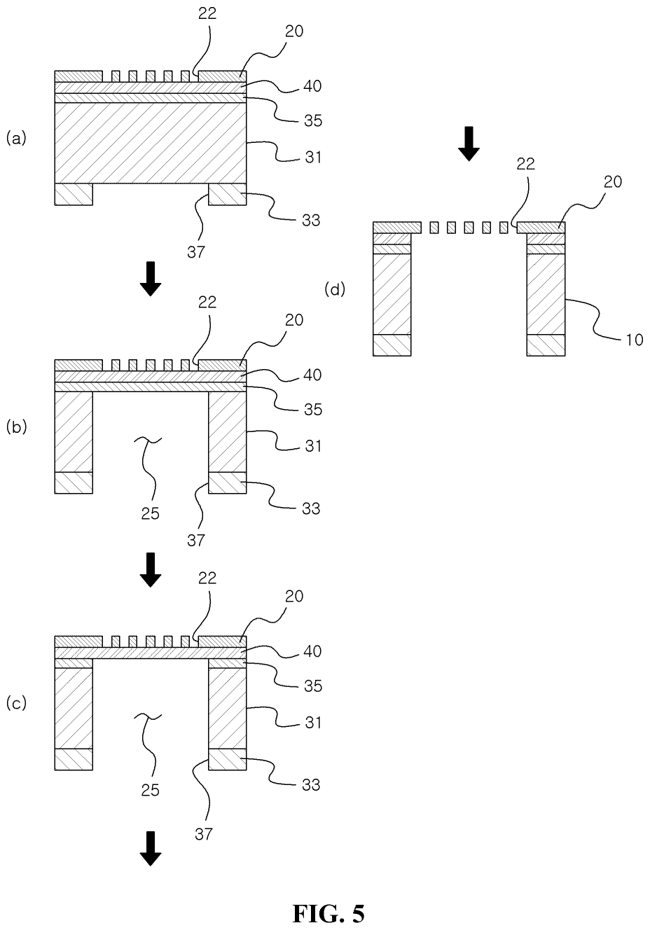

FIG. 2 is a flowchart illustrating a method of manufacturing a shadow mask according to one embodiment of the present invention. In addition, FIG. 3 is a manufacturing process diagram schematically illustrating processes up to forming a mask sheet of FIG. 2, FIG. 4 is a plan view of the shadow mask illustrating welding points in a laser welding process, and FIG. 5 is a manufacturing process diagram schematically illustrating forming of a mask frame of FIG. 2.

The method of manufacturing the shadow mask 100 according to the present embodiment will be described with reference to FIGS. 2 to 5. First, a conductive layer 40 is formed on a base substrate 31 (S11). A material that can be patterned by a semiconductor process may be used as the base substrate 31, and for example, the base substrate 31 made of silicon may be used. In this case, a silicon wafer may be used as the base substrate 31.

A conductive metal such as copper (Cu) may be used as the conductive layer 40, and the conductive layer 40 may be formed by a deposition process such as sputtering.

Before the conductive layer 40 is formed on the base substrate 31, as shown in (a) of FIG. 3, an etch-protection layer 33 may be formed on a lower surface of the base substrate 31, and as shown in (b) of FIG. 3, an adhesive layer 35 may be formed on an upper surface of the base substrate 31. However, the process of forming the etch-protection layer 33 and the adhesive layer 35 is optional and may be omitted as necessary.

As the etch-protection layer 33, a material including silicon nitride (SiNₓ) may be used, and various other materials having a low etch rate may be used. The etch-protection layer 33 functions to protect an edge region of the base substrate 31 from being etched during subsequent etching of the base substrate 31, and this will be described in detail later.

The adhesive layer 35 is used to enhance adhesion between the base substrate 31 and the conductive layer 40 so that the conductive layer 40 is not easily delaminated, and may use a metal material including titanium (Ti). In addition, the adhesive layer 35 may be formed by a deposition method such as sputtering.

After the adhesive layer 35 is formed as described above, the conductive layer 40 may be formed on the adhesive layer 35, as shown in (c) of FIG. 3.

Meanwhile, instead of using the adhesive layer 35, a conductive metal doped with impurities may be used as the conductive layer 40. For example, the conductive layer 40 may be formed using copper doped with magnesium, whereby bonding strength between the conductive layer 40 and the base substrate 31 may be enhanced.

Next, as shown in (d) of FIG. 3, a photoresist 42 is laminated on the conductive layer 40, and the photoresist 42 is patterned into a shape corresponding to mask patterns 22 (S12). Specifically, a photomask having pattern holes corresponding to the mask patterns 22 is disposed on the photoresist 42, and patterning is performed by performing exposure and development processes. For reference, (d) of FIG. 3 illustrates the shape of the photoresist 42 after completion of the patterning process.

Next, as shown in (e) of FIG. 3, a mask sheet 20 is formed by performing electroforming on regions except for the patterned photoresist 42 (S13). Electroforming is performed in a plating bath filled with a plating solution, and when power is supplied by connecting a negative terminal to the conductive layer 40 and a positive terminal to an anode plate located opposite thereto, the conductive layer 40 is plated. As the plating solution, a plating solution containing nickel (Ni) ions and iron (Fe) ions, a plating solution containing nickel (Ni) ions, iron (Fe) ions, and cobalt (Co) ions, or the like may be used.

Next, as shown in (f) of FIG. 3, light treatment is performed to enhance bonding strength between the mask sheet 20 and the conductive layer 40 (S14). As the light treatment, laser welding using laser light L may be performed. In the laser welding, when the laser light L is radiated onto the mask sheet 20, the irradiated region is heated and the region between the mask sheet 20 and the conductive layer 40 is melted, whereby the mask sheet 20 and the conductive layer 40 may be welded to each other.

As illustrated in FIG. 4, laser welding may be performed in outer peripheral regions of a plurality of mask patterns 22 provided on the mask sheet 20. In portions in which the mask patterns 22 are disposed adjacent to each other, laser welding may be performed along boundary regions between the patterns. In this case, welding points P of the laser welding may be set to be spaced a regular interval from each other along outer peripheries of the mask patterns 22.

However, in addition to this method, it is also possible to perform laser welding continuously to form a linear weld seam, and the welding points P may additionally be formed at positions other than those illustrated in the present embodiment, for example, in a peripheral portion of the mask sheet 20.

Next, as shown in (g) of FIG. 3, the photoresist 42 is removed from the conductive layer 40, thereby forming the mask patterns 22 in the portions from which the photoresist 42 has been removed. At this point, the photoresist 42 may be removed by a wet process.

Next, as shown in (a) of FIG. 5, the etch-protection layer 33 is patterned to form a mask-frame forming pattern 37, which is used for patterning the base substrate 31. The mask-frame forming pattern 37, which is formed in the etch-protection layer 33, provides a space into which an etchant can penetrate during a wet etching process, and the etch-protection layer 33 functions to protect the edge region of the base substrate 31 from being etched. Unlike the present embodiment, the patterning of the etch-protection layer 33 may also be performed after the operation of (a) of FIG. 3. Meanwhile, patterning using a photoresist may be possible in addition to the patterning using the etch-protection layer 33.

Next, the base substrate 31 and the conductive layer 40 are patterned so that the mask patterns 22 are exposed, thereby forming a mask frame 10 (S15).

Specifically, as shown in (b) of FIG. 5, the base substrate 31 is etched through the mask-frame forming pattern 37 in the etch-protection layer 33, and at this point, wet etching using an etchant may be used for etching the base substrate 31. According to such an etching process, an etching region 25 may be formed in a central portion of the base substrate 31.

In addition, when the adhesive layer 35 is used as in the present embodiment, the adhesive layer 35 is patterned as shown in (c) of FIG. 5. In this case, patterning may be performed using an etchant that selectively etches the adhesive layer 35.

Next, as shown in (d) of FIG. 5, the conductive layer 40 is patterned through the mask-frame forming pattern 37 in the etch-protection layer 33. This may also be performed by wet etching using an etchant that selectively etches the conductive layer 40, thereby completing the formation of the mask frame 10 and completing the fabrication of a shadow mask. For reference, in the present embodiment, wet etching is illustrated as an example of the patterning method, but the patterning method is not limited thereto, and patterning by dry etching is also possible.

In the present embodiment, the light treatment for enhancing bonding strength between the mask sheet 20 and the conductive layer 40 is exemplified as being performed after the operation shown in (e) of FIG. 3, but such light treatment may be performed before, after, or in the formation of the mask frame 10. In other words, the light treatment may be performed at any operation of the manufacturing process once the mask sheet 20 has been formed, and specifically, the light treatment may be performed after the operations shown in (e) of FIG. 3 and (g) of FIG. 3, and after the operations shown in (a) of FIG. 5 to (d) of FIG. 5.

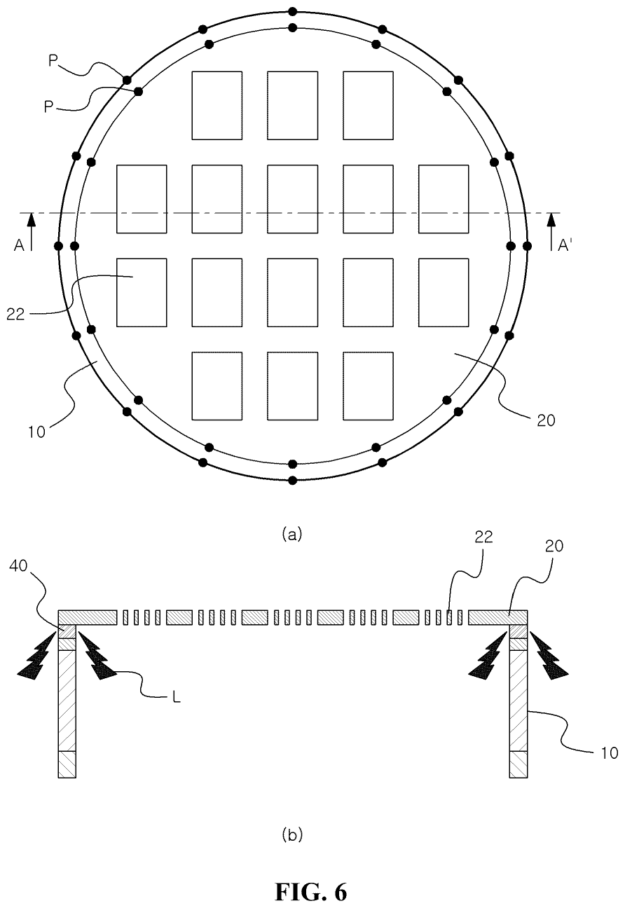

FIG. 6 shows views illustrating another example of welding points in the laser welding process, in which (a) of FIG. 6 illustrates a bottom view of the shadow mask, and (b) of FIG. 6 illustrates a cross-sectional view of the shadow mask.

Unlike what is illustrated in FIG. 4, laser welding may also be performed so that the mask frame 10 and the mask sheet 20 are welded. Specifically, welding may be performed so that the conductive layer 40 of the mask frame 10 and the mask sheet 20 are welded. In the present embodiment, laser welding is exemplified as being performed by radiating the laser light L upward toward the conductive layer 40 after completing the formation of the mask frame 10.

As illustrated in FIG. 6, a plurality of welding points P of the laser welding may be set to be spaced a regular interval from each other along outer and inner circumferences of the mask frame 10.

FIG. 7 shows views illustrating still another example of welding points in the laser welding process, in which (a) of FIG. 7 illustrates a bottom view of the shadow mask, and (b) of FIG. 7 illustrates a cross-sectional view of the shadow mask.

According to FIG. 7, a structure is illustrated in which, in addition to forming the mask frame 10 at an outer periphery of the shadow mask 100, support ribs 15 are formed in boundary regions between the plurality of mask patterns 22. When the mask frame 10 is formed, the support ribs 15 may be formed together and may be formed by forming the mask-frame forming pattern 37 in the etch-protection layer 33 so as to correspond to the regions between the mask patterns 22. By forming the support ribs 15 in this manner, a sagging phenomenon of the mask sheet 20 may be minimized.

In such a case, as shown in FIG. 7, laser welding may be performed so that not only the mask frame 10 and the mask sheet 20 but also the support ribs 15 and the mask sheet 20 are welded. In this case, welding points P between the support ribs 15 and the mask sheet 20 may be set at one or more positions on the support ribs 15.

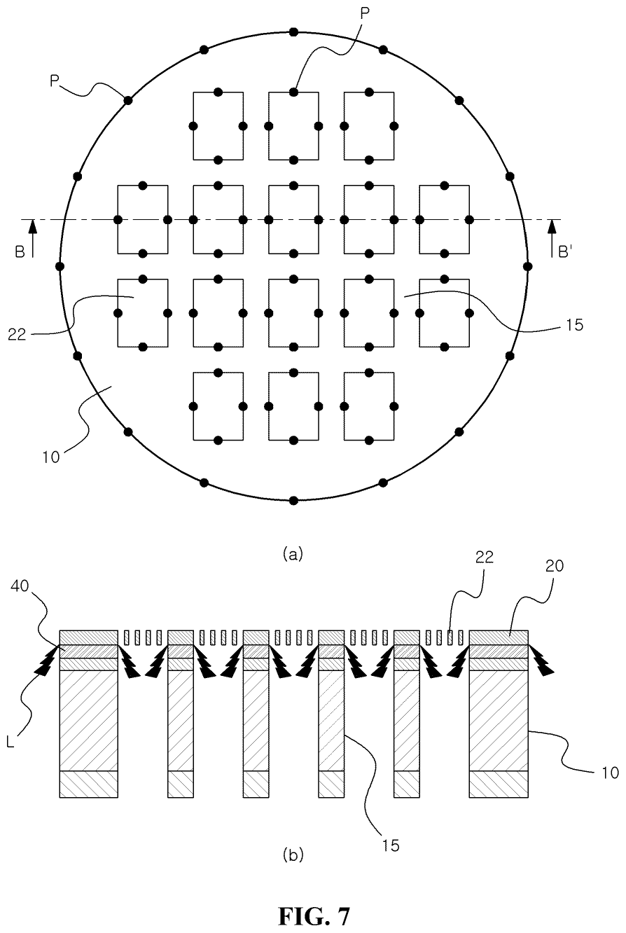

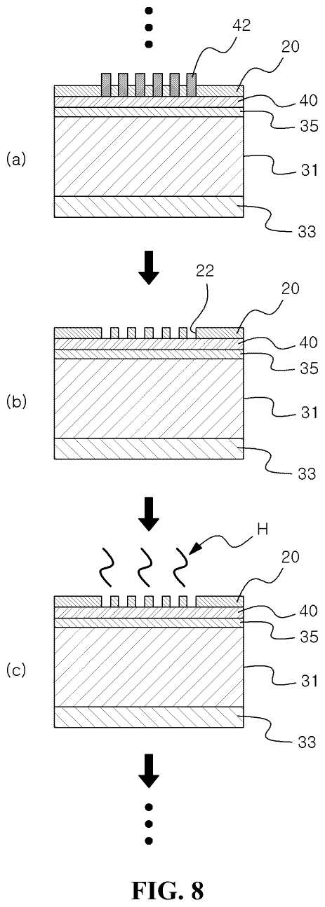

FIG. 8 is a manufacturing process diagram illustrating a method of manufacturing a shadow mask according to another embodiment of the present invention.

In the previous embodiment, light treatment such as laser welding was performed to enhance the bonding strength between the mask sheet 20 and the conductive layer 40, but, instead of such light treatment, heat treatment may be performed as in the present embodiment. As the heat treatment, a heating process performed in a furnace may be used.
(a) of FIG. 8 is the same diagram as (e) of FIG. 3 and illustrates a state in which a mask sheet 20 is formed through electroforming.

Thereafter, as shown in (b) of FIG. 8, after removing a photoresist 42, a heating process using heat H may be performed as shown in (c) of FIG. 8. Accordingly, a conductive layer 40 may be partially melted, thereby enhancing bonding strength with layers located above and below the conductive layer 40.

As in the previous embodiment, the heat treatment may be performed before, after, or in the formation of a mask frame 10. However, the difference from the previous embodiment is that, when heat treatment is performed while the photoresist 42 remains laminated, the photoresist 42 may be affected, for example, by undergoing deformation, which may influence subsequent processes, and thus, it is preferable to perform the heat treatment after removing the photoresist 42 from the mask sheet 20.

In the present embodiment, the heating process in a furnace has been exemplified as the heat treatment method, but heat treatment using a resistance welding process in which current and pressure are applied to a bonding region may also be possible. In this case, welding points may be set in the same manner as the welding points of the laser welding process illustrated in the previous embodiments.

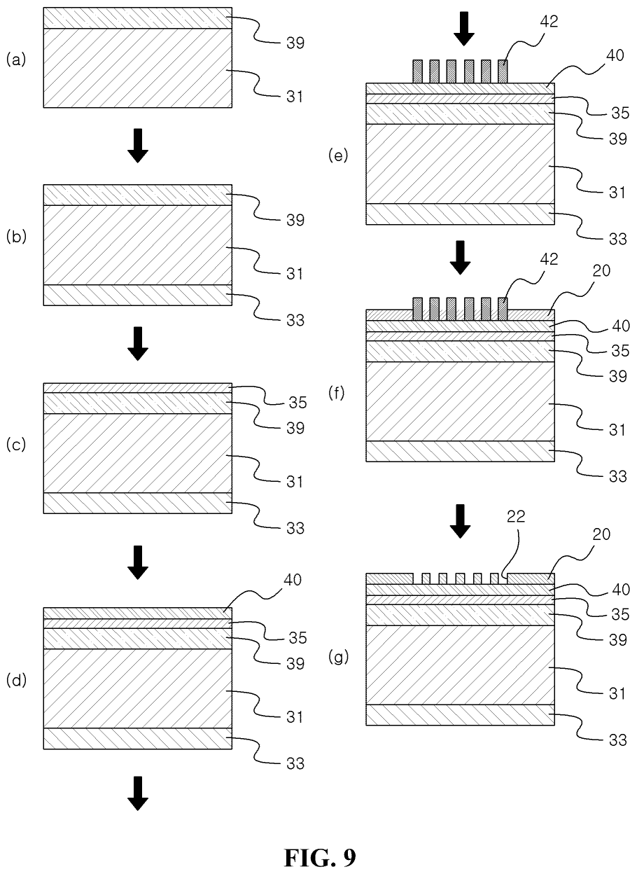

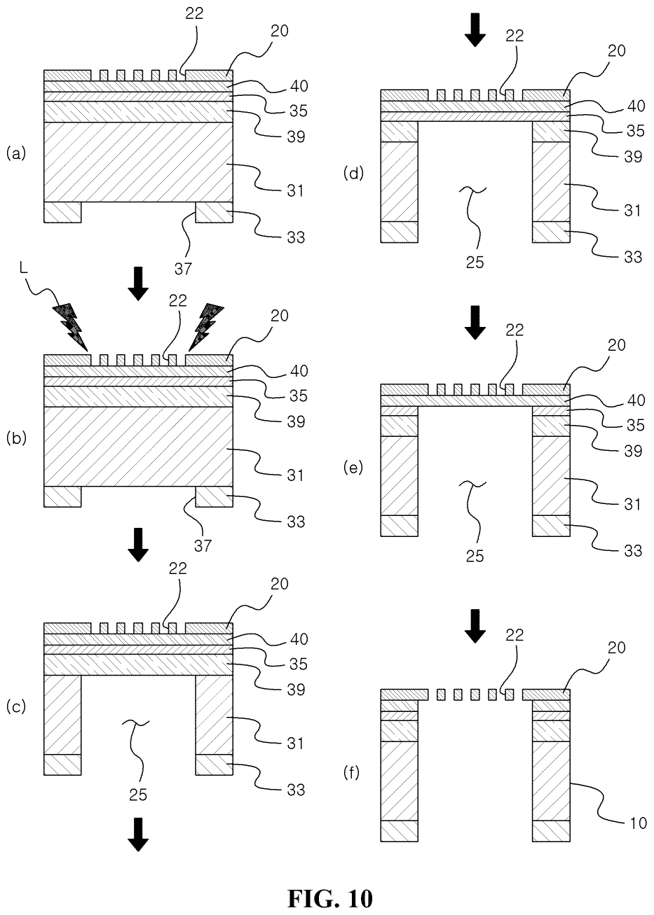

FIGS. 9 and 10 are manufacturing process diagrams illustrating a method of manufacturing a shadow mask according to still another embodiment of the present invention.

In describing the method of manufacturing the shadow mask according to the present embodiment, as shown in (a) of FIG. 9, an insulating film 39 is formed on an upper surface of a base substrate 31, and the insulating film 39 is used as an etch-stop layer when patterning the base substrate 31. As the insulating film 39, a material including silicon oxide (SiO_{y}) may be used, and various other materials capable of being used as an etch-stop layer may also be used.

Next, as shown in (b) of FIG. 9, an etch-protection layer 33 is formed on a lower surface of the base substrate 31, and as shown in (c) of FIG. 9, an adhesive layer 35 is formed on the insulating film. The adhesive layer 35 functions to increase adhesion between the conductive layer 40 and the insulating film.

Next, as shown in (d) of FIG. 9, a conductive layer 40 is formed on the adhesive layer 35 (S11), and as shown in (e) of FIG. 9, a photoresist 42 is laminated on the conductive layer 40 and then patterned. In addition, as shown in (f) of FIG. 9, a mask sheet 20 is formed by performing electroforming on regions except for the patterned photoresist 42, and then, as shown in (g) of FIG. 9, the photoresist 42 is removed from the mask sheet 20.

Next, as shown in (a) of FIG. 10, the etch-protection layer 33 is patterned to form a mask-frame forming pattern 37.

In addition, as shown in (b) of FIG. 10, light treatment such as laser welding is performed on the mask sheet 20 and the conductive layer 40 to enhance bonding strength between the mask sheet 20 and the conductive layer 40. According to the present embodiment, light treatment is exemplified as being performed during the formation of a mask frame 10, but heat treatment may be performed instead of the light treatment.

In addition, as described above, the light treatment and the heat treatment may be performed not only at the operations exemplified in the present embodiment, but also before, after, or in the formation of the mask frame 10.

Next, as shown in (c) of FIG. 10, the base substrate 31 is etched through the mask-frame forming pattern 37 of the etch-protection layer 33. At this point, the insulating film 39 serves as a barrier, i.e., an etch-stop layer, that prevents the layer located thereabove from being unintentionally etched. Accordingly, it becomes possible to prevent the mask sheet 20 from being damaged by an etchant.

Next, as shown in (d) of FIG. 10 to (f) of FIG. 10, the insulating film 39, the adhesive layer 35, and the conductive layer 40 are sequentially patterned through the mask-frame forming pattern 37, thereby forming the mask frame 10, and consequently completing the fabrication of the shadow mask.

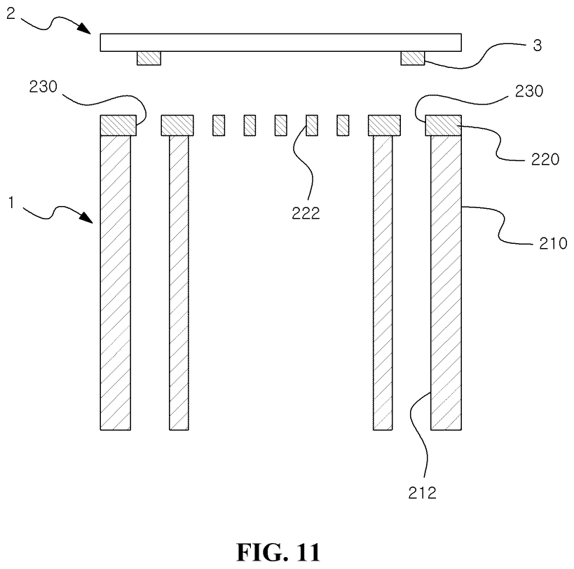

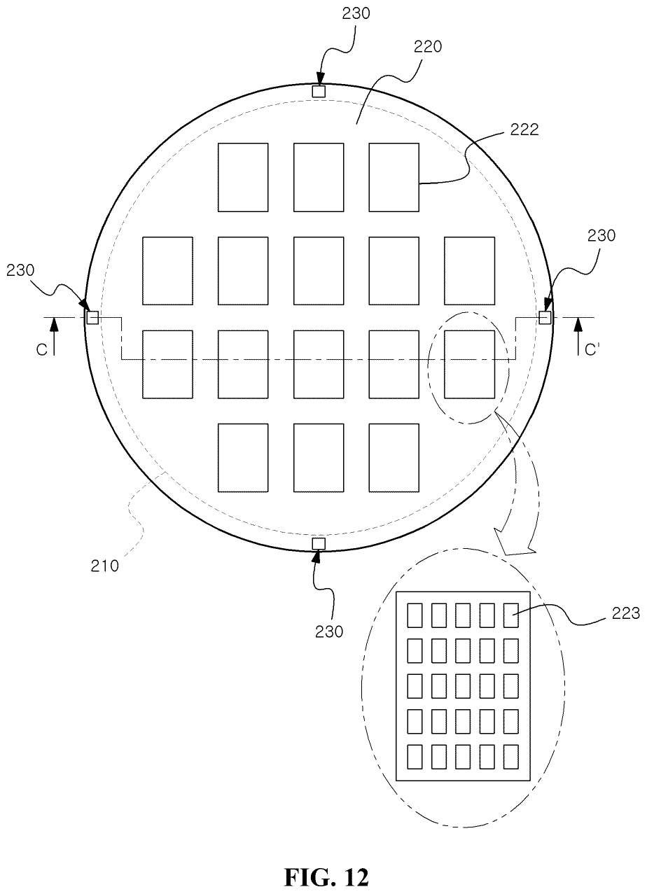

FIG. 11 is a cross-sectional view of a shadow mask for manufacturing an organic light-emitting device according to yet another embodiment of the present invention, showing a state in which the shadow mask is aligned with a substrate to be deposited, and FIG. 12 is a plan view of the shadow mask illustrated in FIG. 11. For reference, the cross-sectional view of the shadow mask in FIG. 11 is taken along line C-C′ of FIG. 12.

As illustrated in FIGS. 11 and 12, a shadow mask 1 for an organic light-emitting device according to the present embodiment includes a mask frame 210 and a mask sheet 220 supported by the mask frame 210.

The mask frame 210 may be supported by a support structure such as a mask holder of vacuum deposition equipment, and may have a shape that supports an edge of the mask sheet 220. The mask frame 210 may have, for example, a ring or donut shape in which a central hole 224 is formed, a mesh shape in which a plurality of through holes are formed at the center, or the like.

The mask sheet 220 includes mask patterns 222 for selectively allowing a deposition material to pass therethrough during a deposition process. As a deposition material evaporated from an evaporation source of a vacuum deposition apparatus passes through the mask patterns 222 and is deposited onto a substrate 2, patterns corresponding to the mask patterns 222 may be formed on the substrate 2. A plurality of mask patterns 222 may be formed on the mask sheet 220, and each of the mask patterns 222 may have a form in which a plurality of fine pattern holes 223 are arranged, as illustrated in FIG. 12.

The mask sheet 220 is formed of a material including Invar (an iron-nickel alloy). An Invar thin film provided with the mask patterns 222 may be formed on a base substrate 241 by electroforming, and the shadow mask 1 may be manufactured by patterning the base substrate 241.

Alignment marks 230 are provided in an outer peripheral region of the mask sheet 220 and are for an alignment with the mask sheet with substrate 2 to be deposited. In addition, through holes 212 may be formed in the mask frame 210 at positions corresponding to the alignment marks 230. Light emitted from a light source of an alignment apparatus passes through the through holes 212 and the alignment marks 230 and reaches alignment keys 3 of the substrate 2, and the substrate 2 and the shadow mask 1 can be aligned by adjusting a relative position between the substrate 2 and the shadow mask 1 based on an image of the alignment keys 3 and the alignment marks 230 obtained from reflected light.

Meanwhile, in addition to the above-described configuration, it is also possible not to form the through holes 212 in the mask frame 210, and to form the alignment marks 230 in an inner region of the mask frame 210.

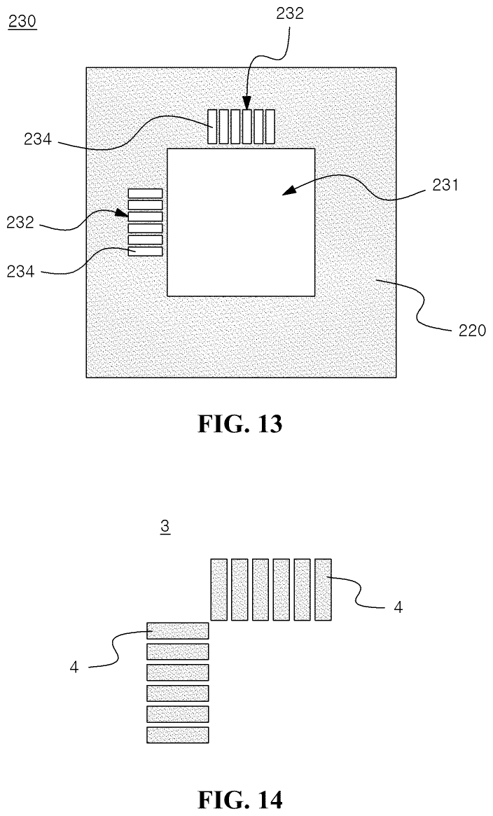

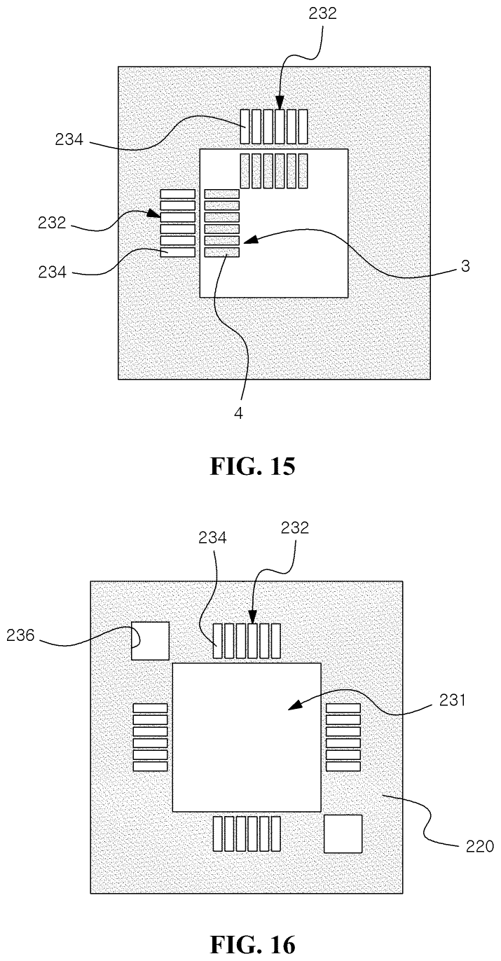

FIG. 13 is a plan view of the alignment mark of the shadow mask illustrated in FIGS. 11 and 12, and FIG. 14 is a plan view of the alignment key of the substrate illustrated in FIG. 11. In addition, FIG. 15 is a plan view illustrating a state in which the alignment mark of the shadow mask illustrated in FIG. 13 and the alignment key of the substrate illustrated in FIG. 14 are aligned with each other.

Referring to FIGS. 13 to 15, the alignment mark 230 includes a window hole 231 and key holes 232, which are formed to pass through the mask sheet 220.

The window hole 231 is formed to pass through the mask sheet 220 so that light emitted from the light source of the alignment apparatus passes therethrough to obtain an image of the alignment key 3 of the substrate 2. To this end, the region of the window hole 231 through which light passes includes a region in which the alignment key 3 is located.

The key hole 232 is formed to pass through at least one side of the window hole 231 for relative alignment with the alignment key 3 of the substrate 2. The window hole 231 may have a polygonal shape, and the key hole 232 may be formed at one side of at least one of the sides of the polygonal shape. In the present embodiment, a structure is exemplified in which the key holes 232 are formed at one side of each of two sides of the window hole 231 having a quadrangular shape.

The alignment key 3 may have a form in which a plurality of pattern keys 4 are arranged at regular intervals, and the key hole 232 may include a plurality of pattern holes 234 formed to correspond to the shapes and positions of the pattern keys 4. As illustrated in the present embodiment, the plurality of pattern keys 4 and the plurality of pattern holes 234 may have bar shapes corresponding to each other, and alignment errors may be minimized by performing data processing (for example, averaging or the like) on data such as the positions and distances between the pattern keys 4 and the pattern holes 234 that correspond to each other.

In describing the alignment process between the substrate 2 and the shadow mask 1, light emitted from the light source of the alignment apparatus passes through the through holes 212 of the mask frame 210 and then passes through the window hole 231 and each of the key holes 232, reaches a region in which the alignment key 3 of the substrate 2 is formed, and is reflected. Through such reflected light, an image in which the pattern keys 4 are located within the window hole 231 may be obtained as illustrated in FIG. 15, and alignment between the shadow mask 1 and the substrate 2 becomes possible by processing image data of the pattern keys 4 and the pattern holes 234.

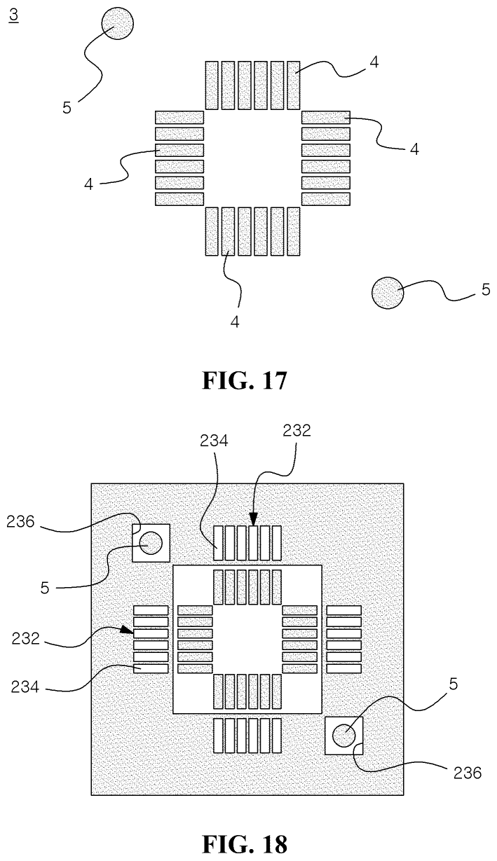

FIG. 16 is a plan view of an alignment mark of a shadow mask according to yet another embodiment of the present invention, and FIG. 17 is a plan view of an alignment key of a substrate according to yet another embodiment of the present invention. In addition, FIG. 18 is a plan view illustrating a state in which the alignment mark of the shadow mask illustrated in FIG. 16 and the alignment key of the substrate illustrated in FIG. 17 are aligned with each other.

According to the present embodiment, auxiliary alignment keys 5 are additionally formed on a substrate 2, and auxiliary key holes 236 corresponding to the auxiliary alignment keys 5 is additionally formed on a mask sheet 220. The auxiliary alignment keys 5 and the auxiliary key holes 236 may be used as an auxiliary means for roughly positioning the substrate 2 and the mask prior to performing fine alignment between the substrate 2 and the mask.

The auxiliary alignment key 5 and the auxiliary key hole 236 may have shapes such as figures, symbols, or marks that match each other. For example, the auxiliary alignment key 5 and the auxiliary key hole 236 may have shapes of matching squares and circles (see FIG. 18), shapes of matching cross marks, or the like.

Meanwhile, in the present embodiment, a structure in which key holes 232 are formed at one side of each of all four sides of a window hole 231 having a quadrangular shape and the auxiliary key holes 236 are located outside two corners of the window hole 231 is exemplified.

When a shadow mask 1 according to the present embodiment is used, a primary alignment (rough alignment) between the substrate 2 and the shadow mask 1 may be performed through the auxiliary key holes 236 and the auxiliary alignment keys 5, and thereafter, a secondary alignment (fine alignment) may be performed by using pattern keys 4 and pattern holes 234.

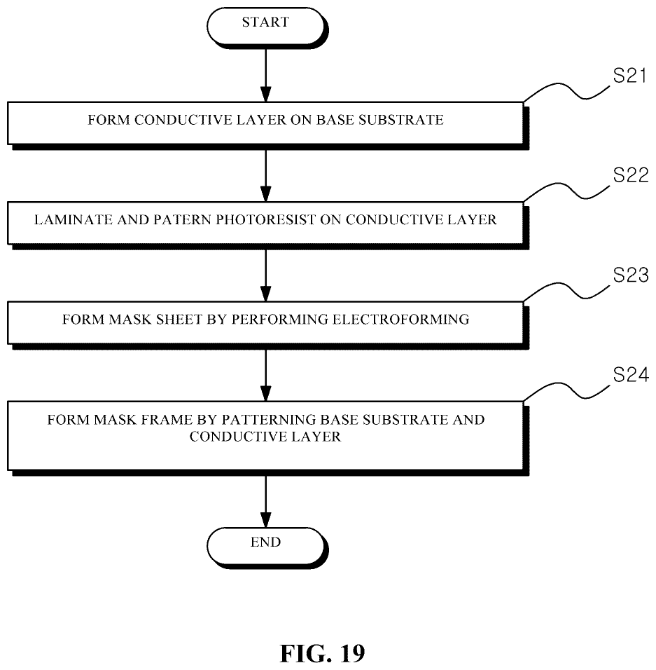

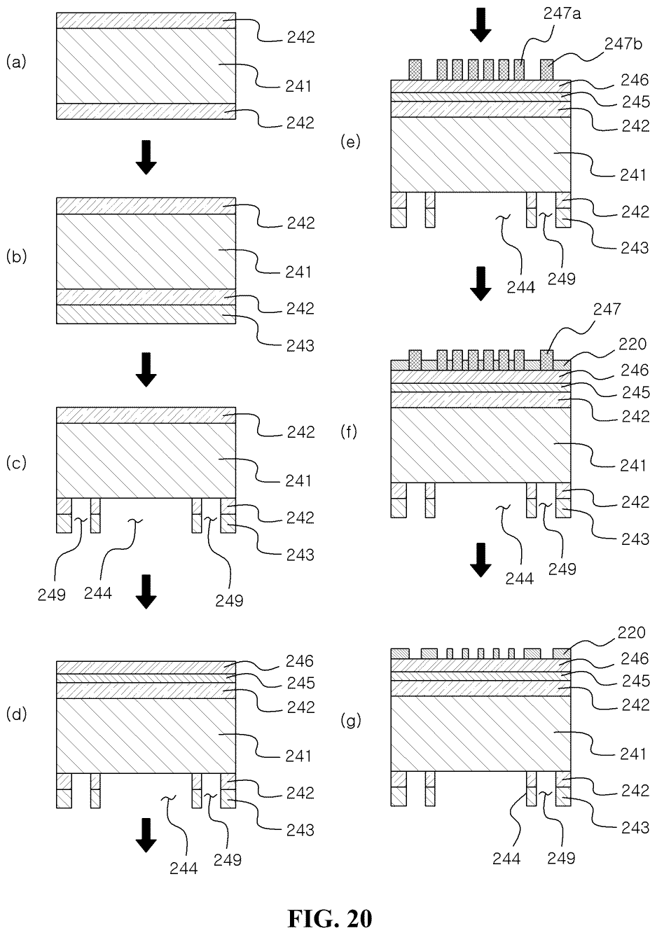

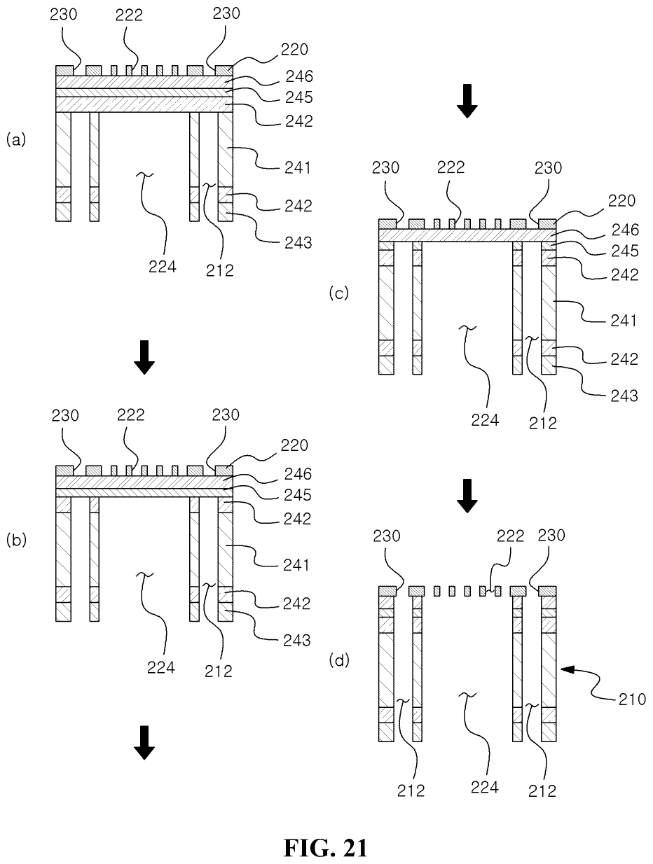

FIG. 19 is a flowchart illustrating a method of manufacturing the shadow mask illustrated in FIG. 11 according to the present invention, and FIGS. 20 and 21 are manufacturing process diagrams schematically illustrating the method of manufacturing the shadow mask illustrated in FIG. 19.

The method of manufacturing the shadow mask according to the present embodiment will be described with reference to FIGS. 19 to 21. First, a conductive layer 246 to be used as an electrode for electroforming is formed on a base substrate 241 (S21).

As shown in (d) of FIG. 20, in the present embodiment, it is exemplified that, before the conductive layer 246 is formed, insulating films 242 functioning as etch-stop layers and an etch-protection layer 243 for protecting the base substrate 241 during patterning are additionally formed. The formation of the insulating films 242 and the etch-protection layer 243 is an optional process, and it is also possible to form the conductive layer 246 directly on the base substrate 241 without forming these layers.

In describing the processes of (a) of FIG. 20 to (c) of FIG. 20, the insulating film 242 is formed on at least one surface of the base substrate 241. A material that can be patterned by a semiconductor process may be used for the base substrate 241 and the insulating film 242. For example, the base substrate 241 made of a silicon material may be used, and in such a case, a silicon wafer may be used as the base substrate 241. As the insulating film 242, a material including silicon oxide (SiOₓ) may be used, and various other materials that can be used as an etch-stop layer may also be used.

In the present embodiment, the base substrate 241 having the insulating films 242 formed on both surfaces, that is, a double-sided laminated substrate, is exemplified, but it is also possible to form the insulating film 242 only on one surface of the base substrate 241, for example, only on an upper surface of the base substrate 241.

Next, as shown in (b) of FIG. 20, the etch-protection layer 243 may be formed on the other surface of the base substrate 241. As the etch-protection layer 243, a material including silicon nitride (SiNₓ) may be used, and various other materials having a low etching rate may be used. Meanwhile, in the present embodiment, a structure is exemplified in which the etch-protection layer 243 is formed on the insulating film 242 on a lower surface of the base substrate 241, but when the insulating film 242 is not formed on the lower surface of the base substrate 241, the etch-protection layer 243 may be formed directly on the lower surface of the base substrate 241.

Next, as shown in (c) of FIG. 20, the etch-protection layer 243 and the insulating film 242 are patterned to form a mask-frame forming pattern 244 and through-hole forming patterns 249, which are used for patterning the base substrate 241. The mask-frame forming pattern 244 and the through-hole forming patterns 249, which are formed in the etch-protection layer 243 and the insulating film 242, provide spaces into which an etchant penetrates during a wet etching process, and the etch-protection layer 243 functions to protect an edge region of the base substrate 241 so that the edge region is not etched.

In the present embodiment in which the insulating film 242 is formed on the base substrate 241, the etch-protection layer 243 and the insulating film 242 are patterned to form the mask-frame forming pattern 244 and the through-hole forming patterns 249, but, when the insulating film 242 is not formed, only the etch-protection layer 243 is patterned to form the mask-frame forming pattern 244 and the through-hole forming patterns 249. In addition, when alignment marks 230 are located in an inner region of a mask frame 210 such that it is unnecessary to form through holes 212, only the mask-frame forming pattern 244 is formed.

Meanwhile, the laminating and patterning of the etch-protection layer 243 illustrated in (b) of FIG. 20 and (c) of FIG. 20 are preliminary operations for patterning the base substrate 241, and the laminating and patterning may not be performed in the present operation but may instead be performed after a mask sheet 220 is formed.

Next, as shown in (d) of FIG. 20, the conductive layer 246 is formed on the insulating film 242. In the present embodiment, it is exemplified that an adhesive layer 245 for enhancing adhesion to the conductive layer 246 is additionally laminated prior to forming the conductive layer 246. In this case, the adhesive layer 245 and the conductive layer 246 may be laminated in this order.

A conductive metal such as copper (Cu) may be used as the conductive layer 246, and a metal material containing titanium may be used as the adhesive layer 245. The conductive layer 246 and the adhesive layer 245 may be formed by a deposition method such as sputtering.

Meanwhile, instead of using the adhesive layer 245, a conductive metal doped with impurities may be used as the conductive layer 246. For example, the conductive layer 246 may be formed using copper doped with magnesium, whereby adhesion between the conductive layer 246 and the base substrate 241 may be enhanced.

Next, as shown in (e) of FIG. 20, a photoresist 247 is laminated on the conductive layer 246, and the photoresist 247 is patterned into shapes corresponding to mask patterns 222, a window hole 231, and a key hole 232 (S22). Specifically, a photomask having pattern holes corresponding to the mask patterns 222 and the alignment marks 230 is disposed on the photoresist 247, and patterning is performed by performing exposure and development processes. For reference, (e) of FIG. 20 illustrates the shape of the photoresist 247 after the patterning is completed, and the photoresist 247 may include a mask-pattern forming portion 247a and an alignment-mark forming portion 247b.

Next, as shown in (f) of FIG. 20, the mask sheet 220 is formed by performing electroforming on regions except for the patterned photoresist 247 (S23). Electroforming is performed in a plating bath filled with a plating solution, and when power is supplied by connecting a negative terminal to the conductive layer 246 and a positive terminal to an anode plate located opposite thereto, the conductive layer 246 is plated. As the plating solution, a plating solution containing nickel (Ni) ions and iron (Fe) ions, a plating solution containing nickel (Ni) ions, iron (Fe) ions, and cobalt (Co) ions, or the like may be used.

In addition, as shown in (g) of FIG. 20, when the photoresist 247 is removed from the conductive layer 246, the portions from which the photoresist 247 is removed form the mask patterns 222 and the alignment marks 230. The photoresist 247 may be removed through a wet process.

Next, as shown in FIG. 21, the base substrate 241 and the conductive layer 246 are patterned so that the mask patterns 222 and the alignment marks 230 are exposed, thereby forming the mask frame 210 (S24).

Specifically, as shown in (a) of FIG. 21, the base substrate 241 is etched through the mask-frame forming pattern 244 and the through-hole forming patterns 249 of the etch-protection layer 243, and wet etching using an etchant may be used for etching the base substrate 241. Through such an etching process, a central hole 224 is formed in a central region of the base substrate 241, and through holes 212 are formed at an edge region. At this point, the insulating film 242 serves as a barrier, i.e., an etch-stop layer, that prevents the layer located thereabove from being unintentionally etched. Accordingly, it becomes possible to prevent the mask sheet 220 from being damaged by an etchant.

Next, as shown in (b) of FIG. 21, the insulating film 242 is patterned through the mask-frame forming pattern 244 and the through-hole forming patterns 249 of the etch-protection layer 243, and this may be performed by wet etching using an etchant that selectively etches the insulating film 242.

Next, as shown in (c) of FIG. 21, the adhesive layer 245 is patterned through the mask-frame forming pattern 244 and the through-hole forming patterns 249 of the etch-protection layer 243. This may be performed by wet etching using an etchant that selectively etches the adhesive layer 245.

Next, as shown in (d) of FIG. 21, the conductive layer 246 is patterned through the mask-frame forming pattern 244 and the through-hole forming patterns 249 of the etch-protection layer 243. This may also be performed by wet etching using an etchant that selectively etches the conductive layer 246, thereby completing the formation of the mask frame 210 and completing the fabrication of a shadow mask 1.

In the present embodiment, the base substrate 241, the insulating film 242, the adhesive layer 245, and the conductive layer 246 are patterned using the etch-protection layer 243, but, in addition to such a method, a patterning method using a photoresist may also be used.

Further, in addition to the wet etching illustrated in the present embodiment, patterning by dry etching may also be possible.

Although the above description has been provided with reference to the specific embodiments of the present invention, it should be understood that those skilled in the art may make various modifications and alterations without departing from the spirit and scope of the present invention as defined in the claims below.

1. A method of manufacturing a shadow mask, comprising:
forming a conductive layer on a base substrate;
laminating a photoresist on the conductive layer and patterning the photoresist into a shape corresponding to a mask pattern;
forming a mask sheet by performing electroforming on regions except for the patterned photoresist;
forming a mask frame by patterning the base substrate and the conductive layer to expose the mask pattern; and
performing light treatment or heat treatment before, after, or in the forming of the mask frame to enhance bonding strength between the mask sheet and the conductive layer.

2. The method of claim 1, wherein the light treatment includes laser welding using laser light.

3. The method of claim 2, wherein the laser welding is performed in outer peripheral regions one mask pattern provided as a plurality of mask patterns on the mask sheet.

4. The method of claim 3, wherein a plurality of welding points of the laser welding are set to be spaced a regular interval from each other along outer peripheries of the mask patterns.

5. The method of claim 2, wherein the laser welding is performed so that the mask frame and the mask sheet are welded.

6. The method of claim 5, wherein a plurality of welding points of the laser welding are set to be spaced a regular interval from each other along outer and inner circumferences of the mask frame.

7. The method of claim 5, wherein:
in the forming of the mask frame, a support rib is formed together between the plurality of mask patterns; and
the laser welding is performed so that the support rib and the mask sheet are welded.

8. The method of claim 1, wherein the heat treatment includes a heating process performed in a furnace or a resistance welding process in which a current and a pressure are applied to a bonding region.

9. The method of claim 8, wherein the heat treatment is performed after the photoresist is removed from the mask sheet.

10. The method of claim 1, further comprising, before the forming of the conductive layer, forming an adhesive layer for enhancing adhesion between the base substrate and the conductive layer.

11. The method of claim 1, wherein the conductive layer is formed of a conductive metal doped with an impurity to enhance adhesion between the base substrate and the conductive layer.

12. The method of claim 1, further comprising, before the forming of the conductive layer, forming an insulating film to be used as an etch-stop layer in the patterning of the base substrate.

13. A shadow mask comprising:
a mask frame;
a mask sheet made of Invar and supported by the mask frame;
a mask pattern formed on the mask sheet to selectively pass a deposition material therethrough during a deposition process; and
an alignment mark formed in an outer peripheral region of the mask sheet for an alignment with a substrate to be deposited,
wherein the alignment mark includes:
a window hole formed to pass through the mask sheet so that light emitted from a light source of an alignment apparatus passes therethrough to obtain an image of an alignment key of the substrate; and
a key hole formed to pass through at least one side of the window hole for relative alignment with the alignment key.

14. The shadow mask of claim 13, wherein:
the window hole has a polygonal shape; and
the key hole is formed at one side of at least one side of the polygonal shape.

15. The shadow mask of claim 13, wherein:
the alignment key has a form in which a plurality of pattern keys are arranged at regular intervals; and
the key hole includes a plurality of pattern holes formed to correspond to shapes and positions of the pattern keys.

16. The shadow mask of claim 13, wherein a through hole is formed in the mask frame at a position corresponding to the alignment mark.

17. The shadow mask of claim 13, wherein:
an auxiliary alignment key is additionally formed on the substrate; and
the alignment mark further includes an auxiliary key hole formed at a position corresponding to the auxiliary alignment key.

18. A method of manufacturing the shadow mask of claim 13, comprising:
forming a conductive layer on a base substrate;
laminating a photoresist on the conductive layer and patterning the photoresist into a shape corresponding to the mask pattern, the window hole, and the key hole;
forming the mask sheet by performing electroforming on regions except for the patterned photoresist; and
forming the mask frame by patterning the base substrate and the conductive layer to expose the mask pattern, the window hole, and the key hole.

19. The method of claim 18, wherein, in the patterning of the base substrate to expose the mask pattern, through holes for exposing the window hole and the key hole are patterned together.

20. The method of claim 18, further comprising, before the forming of the conductive layer, forming an insulating film to be used as an etch-stop layer in the patterning of the base substrate.
